(19) United States
(12) Patent Application Publication
(10) Pub. No.: US 2026/0173266 A1
(43) Pub. Date: Jun. 18, 2026

(54) CIRCUIT SUBSTRATE HAVING IMPROVED BONDING STRUCTURE

(71) Applicant: TONG HSING ELECTRONIC INDUSTRIES, LTD., Taoyuan City (TW)

(72) Inventor: LI-CHUN HUNG, Taoyuan City (TW)

(21) Appl. No.: 19/533,308

(22) Filed: Feb. 9, 2026

Related U.S. Application Data
(63) Continuation of application No. 18/314,099, filed on May 8, 2023.

(30) Foreign Application Priority Data
Dec. 6, 2022 (TW) 111146659

(51) Int. Cl. H05K 1/11; H10W 72/50; H10W 90/00

(52) U.S. Cl. CPC H05K 1/113; H05K 2201/032; H05K 2201/09745; H10W 72/536; H10W 90/754

(57) ABSTRACT

A circuit substrate having an improved bonding structure includes a substrate core layer, an upper protective layer, and at least one bond finger portion. The substrate core layer has a top surface and a bottom surface. The upper protective layer is formed on the top surface of the substrate core layer. The upper protective layer has at least one channel. The at least one bond finger portion is formed on the top surface of the substrate core layer, and is disposed in the at least one channel. A plurality of protrusions are formed on an upper surface of the at least one bond finger portion, so as to increase a bonding area with a bonding wire.

### CROSS-REFERENCE TO RELATED PATENT APPLICATION

This application is a continuation of the U.S. patent application Ser. No. 18/314,099 filed on May 8, 2023 and entitled “CIRCUIT SUBSTRATE HAVING IMPROVED BONDING STRUCTURE.” The entirety of the above-mentioned patent application is hereby incorporated by reference herein and made as a part of this specification.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a circuit substrate having an improved bonding structure, and more particularly to an interposer circuit board that is used as an intermediate element for electrically connecting electrical signals between a printed circuit board and a plurality of semiconductor chips.

### BACKGROUND OF THE DISCLOSURE

In the related art, during a manufacturing process of a semiconductor package structure, a wire bonding technology has been widely applied to electrical connection between contact pads 92 of a chip 9 and solder pads 82 of a substrate 8 (as shown in FIG. 1). A bonding wire W used in the wire bonding process can be a gold wire or a copper wire.

After a first end W1 of the bonding wire W is connected to the contact pad 92 of the chip 9, a bonding ball W2 at a second end of the bonding wire W is connected to the solder pad 82 of the substrate 8. However, during the wire bonding process, poor eutectic soldering between the bonding wire W and the solder pad 82 of the substrate 8 may result in a ball lift problem.

Therefore, how to enhance bonding effectiveness of a substrate through an improvement in structural design, so as to overcome the above-mentioned deficiencies, has become one of the important issues to be solved in this industry.

### SUMMARY OF THE DISCLOSURE

In response to the above-referenced technical inadequacies, the present disclosure provides a circuit substrate having an improved bonding structure.

In order to solve the above-mentioned problems, one of the technical aspects adopted by the present disclosure is to provide a circuit substrate having an improved bonding structure, which includes a substrate core layer, an upper protective layer, and at least one bond finger portion. The substrate core layer has a top surface and a bottom surface. The upper protective layer is formed on the top surface of the substrate core layer. The upper protective layer has at least one channel. The at least one bond finger portion is formed on the top surface of the substrate core layer, and is disposed in the at least one channel. A plurality of protrusions are formed on an upper surface of the at least one bond finger portion forms, so as to increase a bonding area with a bonding wire.

Therefore, in the circuit substrate having the improved bonding structure provided by the present disclosure, through the protrusions formed on the upper surface of the at least one bond finger portion, the bonding area between the at least one bond finger portion and the bonding wire is increased. In this way, occurrence of a ball lift event in the bonding wire can be reduced, thereby improving a yield rate in a wire bonding process of a semiconductor package structure.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a schematic view illustrating a chip being bonded to a substrate in the related art;

FIG. 2 is a perspective view of a circuit substrate having an improved bonding structure according to a first embodiment of the present disclosure;

FIG. 3 is a front view of the circuit substrate having the improved bonding structure after bonding according to the first embodiment of the present disclosure;

FIG. 4 is a perspective view of the circuit substrate having the improved bonding structure according to a second embodiment of the present disclosure;

FIG. 5 is a front view of the circuit substrate having the improved bonding structure after bonding according to the second embodiment of the present disclosure; and

FIG. 6 is a perspective view of the circuit substrate having the improved bonding structure according to a third embodiment of the present disclosure.

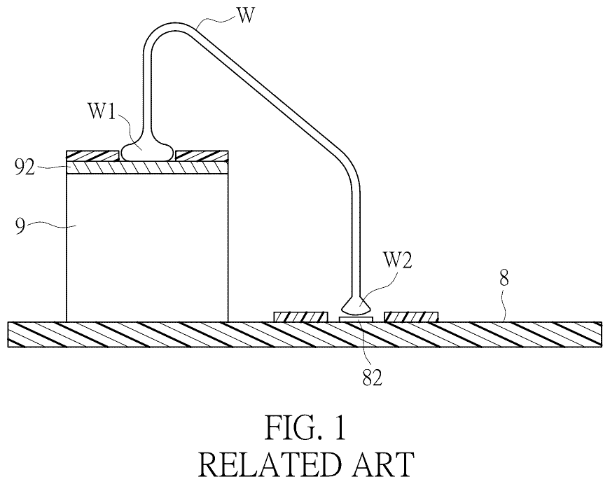

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a,” “an” and “the” includes plural reference, and the meaning of “in” includes “in” and “on.” Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first,” “second” or “third” can be used to describe various components, signals or the like, which are for distinguishing one component/signal from another one only, and are not intended to, nor should be construed to impose any substantive limitations on the components, signals or the like.

### First Embodiment

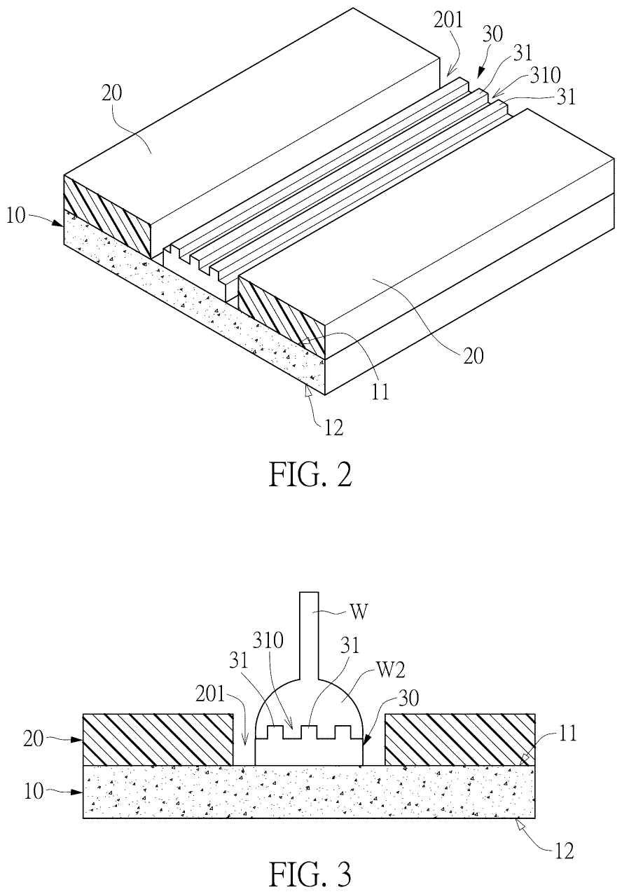

Referring to FIG. 2 and FIG. 3, a first embodiment of the present disclosure provides a circuit substrate having an improved bonding structure (or hereinafter referred to as a circuit substrate). The circuit substrate includes a substrate core layer 10, an upper protective layer 20, and a bond finger portion 30. While one bond finger portion 30 is exemplified in the figures of this embodiment, a quantity of the bond finger portion 30 is not limited thereto. There can be more than one bond finger portion 30. The circuit substrate of this embodiment can be an interposer, but the present disclosure is not limited thereto.

The substrate core layer 10 has a top surface 11 and a bottom surface 12. Taking an interposer as an example, the substrate core layer 10 can be made of metal or polymer material. For example, the material of the substrate core layer 10 can be made of copper foil or glass fiber. The copper foil is used as a middle core layer of the substrate core layer 10, and provides a supporting function. An insulation film is formed on upper and lower surfaces of the copper foil. After an etching process, a bonding finger is formed on the insulation film.

The upper protective layer 20 is disposed on the top surface 11 of the substrate core layer 10. The upper protective layer 20 is made of an insulating material (preferably a low dielectric material). The upper protective layer 20 has at least one channel 201, and the channel 201 is exposed from the top surface 11 of the substrate core layer 10.

The bond finger portion 30 is formed on the top surface 11 of the substrate core layer 10, and is disposed in the channel 201. The bond finger portion 30 can be made of copper, aluminum, copper alloy, or aluminum alloy. However, the present disclosure is not limited thereto. For example, the bond finger portion 30 may be made of gold or silver. One structural characteristic of this embodiment is that an upper surface of the bond finger portion 30 forms a plurality of protrusions 31, so that a bonding area between the bond finger portion 30 and a bonding wire W can be increased. A width of the bond finger portion 30 can be greater than or equal to a diameter of a bonding ball of the bonding wire W. The upper surface of the bond finger portion 30 is lower than a top surface of the upper protective layer 20. Alternatively, the upper surface of the bond finger portion 30 can be flush with the top surface of the upper protective layer 20.

In this embodiment, the bond finger portion 30 forms a plurality of linear grooves 310 that are parallel to each other. A depth of the linear grooves 310 is less than a thickness of the bond finger portion 30. The linear grooves 310 can be formed in a longitudinal direction of the bond finger portion 30. However, the present disclosure is not limited thereto. For example, the linear grooves 310 can also be formed in a direction perpendicular to the longitudinal direction of the bond finger portion 30. Each of the protrusions 31 is stripe-shaped, and the bond finger portion 30 has a fin shape. The bond finger portion 30 can be made by a photo mask and etching process. In this embodiment, through the linear grooves 310, a contact area between the bond finger portion 30 and the bonding wire W is increased, so that a bonding strength between a bonding ball W2 (or referred to as a ball shaped portion) at a second end of the bonding wire W and the bond finger portion 30 can be enhanced, and a ball lift problem can be reduced.

### Second Embodiment

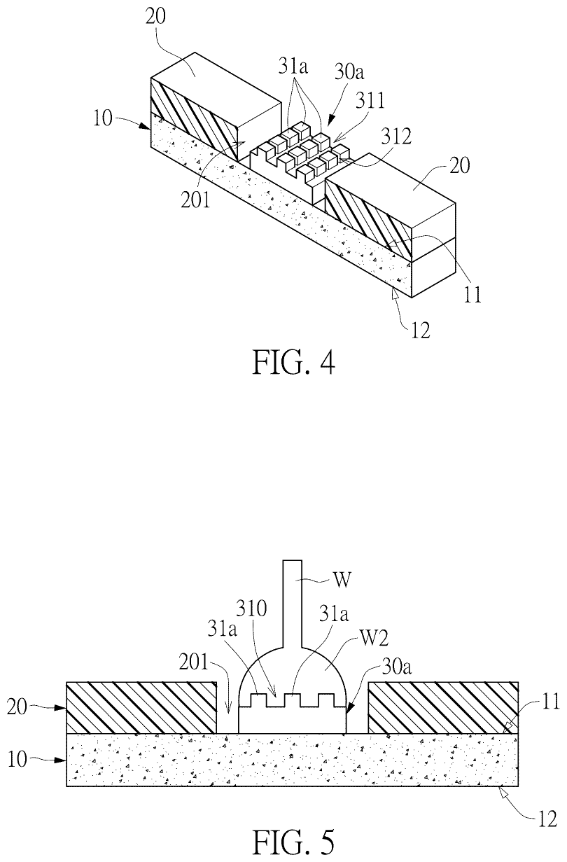

Referring to FIG. 4 and FIG. 5, this embodiment is different from the previous embodiment in that a plurality of grooves that intersect with each other (e.g., a plurality of longitudinal grooves 311 and a plurality of traverse grooves 312) are formed on a bond finger portion 30a, and that protrusions 31a are columnar-shaped. In detail, the longitudinal grooves 311 are parallel to each other. and are parallel to the longitudinal direction of the bond finger portion 30a. The traverse grooves 312 are parallel to each other, and are perpendicular to a longitudinal direction of the bond finger portion 30a. The protrusions 31a are square columnar-shaped.

A depth of the grooves (which include the longitudinal grooves 311 and the traverse grooves 312) is less than a thickness of the bond finger portion 30a.

In this embodiment, a contact area between the bond finger portion 30a and the bonding wire W is more than that of the first embodiment.

### Third Embodiment

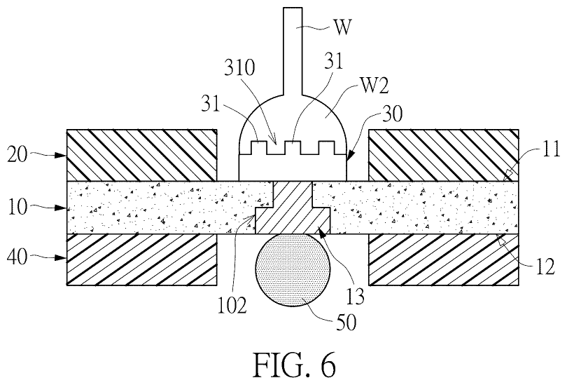

As shown in FIG. 6, the circuit substrate of this embodiment is exemplified as an interposer. The circuit substrate further includes a lower protective layer 40. The lower protective layer 40 is disposed on the bottom surface 12 of the substrate core layer 10. Similar to the upper protective layer 20, the lower protective layer 40 is made of an insulating material (preferably a low dielectric material). The substrate core layer 10 can be made of metal or polymer material. For example, the material of the substrate core layer 10 can be made of copper or glass fibers.

The bottom surface 12 of the substrate core layer 10 further includes at least one solder bump 50. The substrate core layer 10 further has at least one through hole 102, and at least one metal inner conducting wire 13. The through hole 102 passes through the substrate core layer 10. The metal inner conducting wire 13 is disposed in through hole 102, and electrically connects to the bond finger portion 30 and the solder bump 50.

The substrate core layer 10 of this embodiment is exemplified as having a single layer. However, the present disclosure is not limited to the above-mentioned examples. The interposer can be a multi-layer structure, and soldering pads that are connected to a flip chip can also be disposed on a top surface of the interposer.

### Beneficial Effects of the Embodiments

In conclusion, in the circuit substrate having the improved bonding structure provided by the present disclosure, through the protrusions formed on the upper surface of the at least one bond finger portion, the bonding area between the bond finger portion and the bonding wire is increased. In this way, occurrence of a ball lift event in the bonding wire can be reduced, thereby improving a yield rate in the wire bonding process in the manufacturing process of a semiconductor package structure.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A circuit substrate having an improved bonding structure, comprising:
a substrate core layer having a top surface and a bottom surface;
an upper protective layer formed on the top surface of the substrate core layer, the upper protective layer having at least one channel; and
at least one bond finger portion formed on the top surface of the substrate core layer and disposed in the at least one channel, wherein two lateral sides of the at least one bond finger portion are respectively spaced apart from two inner sides of the at least one channel, and a part of the top surface of the substrate core layer is exposed from the at least one channel, and wherein the at least one bond finger portion is a single one-piece structure having a plurality of protrusions that are arranged on an upper side thereof;
wherein the plurality of protrusions are jointly configured to be distributed positionally corresponding to a bottom of a ball shaped portion of a bonding wire, and are mutually engaged with the bottom of the ball shaped portion of the bonding wire.

2. The circuit substrate according to claim 1, wherein the upper surface of the at least one bond finger portion is lower than a top surface of the upper protective layer.

3. The circuit substrate according to claim 1, wherein the at least one bond finger portion has a plurality of linear grooves that are parallel to each other and that are recessed in the upper surface thereof, each of the protrusions is stripe-shaped, and the at least one bond finger portion has a fin shape.

4. The circuit substrate according to claim 3, wherein a depth of each of the linear grooves is less than a thickness of the at least one bond finger portion.

5. The circuit substrate according to claim 1, wherein the at least one bond finger portion has a plurality of grooves that intersect with each other and that are recessed in the upper surface thereof, and the protrusions are columnar-shaped.

6. The circuit substrate according to claim 5, wherein a depth of each of the grooves is less than a thickness of the at least one bond finger portion.

7. The circuit substrate according to claim 1, wherein the at least one bond finger portion is made of copper, aluminum, copper alloy, or aluminum alloy.

8. The circuit substrate according to claim 1, further comprising a lower protective layer, wherein the substrate core layer is made of metal or a polymer material, and the lower protective layer is formed on the bottom surface of the substrate core layer.

9. The circuit substrate according to claim 8, wherein at least one solder bump is further disposed on the bottom surface of the substrate core layer.

10. The circuit substrate according to claim 9, wherein the substrate core layer further has at least one through hole and includes at least one metal inner conducting wire, and the at least one through hole passes through the substrate core layer; wherein the at least one metal inner conducting wire is disposed in the at least one through hole, and is electrically connected to the at least one bond finger portion and the at least one solder bump.

11. The circuit substrate according to claim 1, wherein an outer surface of the ball shaped portion of the bonding wire is flush with the two lateral sides of the at least one bond finger portion.

12. A circuit substrate having an improved bonding structure, comprising:
a substrate core layer having a top surface and a bottom surface;
an upper protective layer formed on the top surface of the substrate core layer and having two regions that are spaced apart from each other; and
a bond finger portion formed on the top surface of the substrate core layer and arranged between the two regions of the upper protective layer, wherein two lateral sides of the bond finger portion are respectively free from contacting the two regions of the upper protective layer, and wherein the bond finger portion is a single one-piece structure having a plurality of protrusions that are arranged on an upper side thereof;
wherein the plurality of protrusions are lower than a top surface of each of the two regions of the upper protective layer.

13. The circuit substrate according to claim 12, wherein the top surface of the substrate core layer, the two regions of the upper protective layer, and the two lateral sides of the bond finger layer jointly define two channels, and wherein any one of the two lateral sides of the bond finger portion is free from contacting a corresponding one of the two regions of the upper protective layer by one of the two channels.

14. The circuit substrate according to claim 13, wherein the bond finger portion has a plurality of linear grooves that are parallel to each other and that are recessed in the upper surface thereof, and wherein any two of the plurality of linear grooves adjacent to each other are provided with one of the protrusions arranged therebetween.

15. The circuit substrate according to claim 13, wherein the bond finger portion has a plurality of linear grooves that are parallel to each other and that are recessed in the upper surface thereof, and wherein two of the plurality of linear grooves respectively arranged adjacent to the two regions of the upper protective layer are respectively in spatial communication with the two channels.

16. The circuit substrate according to claim 15, further comprising a bonding wire that has a ball shaped portion connected to the protrusions of the finger portion, wherein an outer surface of the ball shaped portion of the bonding wire is flush with the two lateral sides of the bond finger portion, and wherein the plurality of linear grooves are fully filled with the ball shaped portion of the bonding wire.

17. The circuit substrate according to claim 12, wherein the at least one bond finger portion has a plurality of grooves that intersect with each other and that are recessed in the upper surface thereof.

18. The circuit substrate according to claim 12, further comprising a bonding wire that has a ball shaped portion connected to the protrusions of the finger portion, wherein an outer surface of the ball shaped portion of the bonding wire is flush with the two lateral sides of the bond finger portion.

19. The circuit substrate according to claim 18, wherein the top surface of the substrate core layer, the two regions of the upper protective layer, the two lateral sides of the bond finger layer, and the outer surface of the ball shaped portion of the bonding wire jointly define two channels, and wherein any one of the two lateral sides of the bond finger portion is free from contacting a corresponding one of the two regions of the upper protective layer by one of the two channels.

20. The circuit substrate according to claim 12, wherein the substrate core layer further has a through hole and includes an inner conducting wire, and the through hole passes through the substrate core layer and is arranged lower than the bond finger portion, and wherein the metal inner conducting wire is disposed in the through hole and is electrically connected to the bond finger portion and the solder bump.
